(19) United States
(12) Patent Application Publication
(10) Pub. No.: US 2025/0301828 A1
(43) Pub. Date: Sep. 25, 2025

(54) FLIP-CHIP HIGH-VOLTAGE LIGHT-EMITTING DIODE

(71) Applicant: HUAIAN AUCKSUN OPTOELECTRONICS TECHNOLOGY CO., LTD, Huaian (CN)

(72) Inventors: Dongmei LI, Huaian (CN); Congkang JIANG, Huaian (CN); Sibo WANG, Huaian (CN); Han-Chung LIAO, Huaian (CN); Ling LU, Huaian (CN)

(73) Assignee: HUAIAN AUCKSUN OPTOELECTRONICS TECHNOLOGY CO., LTD, Huaian (CN)

(21) Appl. No.: 18/861,894

(22) PCT Filed: Jun. 30, 2023
(86) PCT No.: PCT/CN2023/105362

§ 371 Date: Oct. 31, 2024

(30) Foreign Application Priority Data
Jul. 14, 2022 (CN) 202210834610.6

(51) Int. Cl. H10H 20/821; H10H 20/813

(52) U.S. Cl. CPC H10H 20/821; H10H 20/8132

(57) ABSTRACT

The present application relates to the technical field of light-emitting diodes, and particularly relates to a flip-chip high-voltage light-emitting diode. The present application designs on one light-emitting unit a protruding part which faces the center position of the flip-chip high-voltage light-emitting diode, so that a vulnerable position of an isolation groove is prevented from being pressed against by an ejector pin, and meanwhile, a situation of electric leakage caused by film layer breakage is avoided, thereby improving reliability.

### CROSS-REFERENCE TO RELATED APPLICATION

The present disclosure claims priority to Chinese patent Application No. 202210834610.6, filed with the Chinese Patent Office on Jul. 14, 2022, entitled “FLIP-CHIP HIGH-VOLTAGE LIGHT-EMITTING DIODE,” the entire contents of which are incorporated herein by reference.

### TECHNICAL FIELD

The present disclosure relates to the technical field of the light-emitting diode, and specifically to a flip high-voltage light-emitting diode ((i.e., flip-chip high-voltage light-emitting diode).

### BACKGROUND ART

The flip high-voltage chip is made by series connecting a plurality of independent flip light-emitting diode chips, and combines advantages of the flip light-emitting diode and the high-voltage light-emitting diode, such as high luminous efficiency, high reliability, low cost, high driving efficiency, and other advantages, so as to be widely used in lighting, backlighting, mini LED, and other fields.

As shown in FIG. 1 and FIG. 2, the flip high-voltage chip is composed of two light-emitting units by connecting electrode in series, and the two light-emitting units are separated by an isolation groove. Each light-emitting unit includes an epitaxial structure, a transparent conductive layer, electrodes, a protective layer for protecting the epitaxial structure, the transparent conductive layer, and the electrodes, and a bonding pad. The protective layer is usually made of a material of silicon oxide, or is a distributed Bragg reflector composed of silicon oxide and titanium oxide.

When sorting or packaging the prior flip high-voltage light-emitting diode, an ejector pin is needed to act on a certain area of the flip high-voltage light-emitting diode to lift it up and sort or fix the wafer. As shown in FIG. 3 and FIG. 4, the ejector pin often acts on the center area of the flip high-voltage light-emitting diode, wherein this is usually a position of the isolation groove, and it is usually connected to the electrode film layer and the protective layer. When packaging the chip, the ejector pin needs to lift it to fix the wafer from the front side of the chip, i.e., the ejector pin may break through the film protective layer when the ejector pin directly reacts on the protective layer, so as to result in an electric leakage. When sorting, although the ejector pin directly acts on the back side of the chip, after the ejector pin lifts up, a strong suction nozzle is required to adsorb from the front side of the chip and then transfer to a position where it needs to be fixed, which may also lead to rupture of the protective layer during the adsorption process.

In view of this, the present disclosure is provided.

### SUMMARY

A first object of the present disclosure is to provide a flip high-voltage light-emitting diode, wherein one light-emitting unit has a protruding part facing a center position of the flip high-voltage light-emitting diode, which avoids an ejector pin from abutting against a vulnerable position of an isolation groove, and avoids a condition of electric leakage caused by film layer breakage, so as to improve the reliability.

In order to realize the above object, the present disclosure adopts following technical solutions.

A flip high-voltage light-emitting diode includes:
a base board;
at least two light-emitting units, located on the base board, wherein each two adjacent light-emitting units are isolated by an isolation groove, each light-emitting unit includes at least a N-type semiconductor layer, a light-emitting layer, a P-type semiconductor layer, and a first N electrode electrically connected to the N-type semiconductor layer and a first P electrode electrically connected to the P-type semiconductor layer; and
and at least one connection electrode, electrically connecting the P-type semiconductor layer and the N-type semiconductor layer of the adjacent light-emitting units respectively, wherein
at least one light-emitting unit has a protruding part facing a center position of the flip high-voltage light-emitting diode, and the protruding part is isolated from adjacent light-emitting unit by the isolation groove, wherein a width of the protruding part is larger than a width of the isolation groove.

Preferably, the light-emitting unit with the protruding part is defined as a first light-emitting unit, and the other light-emitting unit closest to the first light-emitting unit is defined as a second light-emitting unit, wherein the first light-emitting unit and the second light-emitting unit are of asymmetric structures.

Preferably, the second light-emitting unit has a recessed part corresponding to the protruding part, wherein a projection of the protruding part in a horizontal direction is of a shape of at least one of a circular arc, a square, a triangle, a rectangle, or a polygon.

Preferably, a relationship between a length W of the protruding part and a length M of the first light-emitting unit is ⅓M≤W≤½M.

More preferably, 15 μm≤W≤50 μm.

Preferably, the flip high-voltage light-emitting diode comprises a first electrode layer, a second electrode layer, and a bonding pad electrode layer sequentially arranged in an outward extension direction of the base board, wherein
the first electrode layer includes a plurality of first N-type electrodes and first P-type electrodes dispersedly arranged on each light-emitting unit respectively;
the second electrode layer includes a second P-type electrode, a second N-type electrode, and a PN connection electrode connecting to the first P-type electrode and the first N-type electrode of adjacent light-emitting units; and
the bonding pad electrode layer includes the P-type bonding pad electrode electrically connecting the second P-type electrode and the N-type bonding pad electrode electrically connecting the second N-type electrode, wherein
the PN connection electrode includes one second electrode opening, and the second electrode opening completely exposes the protruding part.

Preferably, the second electrode opening is arranged on the first light-emitting unit, or arranged on the first light-emitting unit and partial isolation groove.

Preferably, a shape of the second electrode opening is matched with a shape of the protruding part, or matched with a mirror shape of the protruding part.

Preferably, the flip high-voltage light-emitting diode further includes a third electrode layer arranged between the second electrode layer and the bonding pad electrode, and the third electrode layer includes a third P-type electrode, a third N-type electrode, and a third center electrode arranged on an upper part of the second electrode opening, wherein
the third P-type electrode, the third N-type electrode, and the third center electrode are not connected to each other.

Preferably, the third P-type electrode is provided with a third P-type through hole, and the third P-type through hole is configured to expose the second P-type electrode.

Preferably, the third N-type electrode is provided with a third N-type through hole, and the third N-type through hole is configured to expose the second N-type electrode.

Preferably, the third electrode layer is insulated from the second electrode layer and the bonding pad electrode layer respectively, wherein
the second electrode layer is electrically connected to the bonding pad electrode layer.

More preferably, an area of the third electrode layer occupies 60% ˜90% of a total area of the flip light-emitting diode.

More preferably, the third center electrode is totally or partially arranged on the second electrode opening.

More preferably, at least 70% of the third center electrode is arranged on the second electrode opening.

More preferably, the third center electrode is arranged on the first light-emitting unit.

More preferably, the third center electrode is arranged on a center region of the flip high-voltage light-emitting diode.

Preferably, an outermost edge of the protruding part is closer to the isolation groove than an outermost edge of the third center electrode, wherein a difference between shortest horizontal distances is larger than 0 and smaller than or equal to 5 μm, and the shortest horizontal distances are distances separately between the outermost edge of the protruding part and the isolation groove and between the outermost edge of the third center electrode and the isolation groove.

Compared with the prior art, the present disclosure includes the following beneficial effects.

(1) The present disclosure provides the flip high-voltage light-emitting diode, wherein one light-emitting unit has the protruding part facing the center position of the flip high-voltage light-emitting diode, which avoids the ejector pin from abutting against the vulnerable position of the isolation groove, and avoids the condition of electric leakage caused by film layer breakage, so as to improve the reliability.

(2) In the present disclosure, the third electrode layer is arranged between the second electrode layer (Metal layer) and the bonding pad layer, wherein the third electrode layer is insulated from both the second electrode layer and the bonding pad layer, and the second electrode is electrically connected to the bonding pad layer, which can effectively avoid the condition of the electric leakage caused by film layer breakage, so as to improve the reliability.

### BRIEF DESCRIPTION OF DRAWINGS

In order to more clearly illustrate the technical solutions in the specific embodiments or prior art of the present disclosure, the drawings to be used in the description of the specific embodiments or prior art will be briefly introduced below. It is obvious that the drawings in the following description are some embodiments of the present disclosure, and for persons of ordinary skill in the art, other drawings can be obtained based on these drawings without inventive efforts.

FIG. 1 shows a design schematic diagram of an ejector pin position in the prior art;

FIG. 2 shows a sectional schematic diagram of FIG. I cutting along a direction of an arrow;

FIG. 3 shows a sectional schematic diagram of a position relationship of a sorting ejector pin and a chip in the prior art;

FIG. 4 shows a sectional schematic diagram of a position relationship of a wafer fixing ejector pin and a chip in the prior art;

FIG. 5 shows a plane schematic diagram of a flip high-voltage light-emitting diode chip provided by the embodiment of the present disclosure;

FIG. 6 shows a sectional schematic diagram of FIG. 5 cutting along a direction of an arrow;

FIG. 7 shows a sectional schematic diagram of a position relationship of a chip and a sorting ejector pin of the embodiment of the present disclosure;

FIG. 8 shows a sectional schematic diagram of a position relationship of a chip and a wafer fixing ejector pin of the embodiment of the present disclosure;

FIG. 9 shows a schematic diagram of a plane design of a first electrode layer of the embodiment of the present disclosure;

FIG. 10 shows a partially enlarged schematic diagram of a protruding part of a dashed part of FIG. 9;

FIG. 11 shows a schematic diagram of a plane design of a second electrode layer of the embodiment of the present disclosure;

FIG. 12 shows a schematic diagram of a plane design of a second electrode layer of another embodiment of the present disclosure;

FIG. 13 shows a schematic diagram of a plane design of a third electrode layer of the embodiment of the present disclosure;

FIG. 14 shows a schematic diagram of a plane design of a bonding pad layer of the embodiment of the present disclosure;

FIG. 15 shows a schematic diagram of a position relationship between a bonding pad layer and a second electrode layer of the embodiment of the present disclosure;

FIG. 16 shows a structure schematic diagram of four light-emitting units provided by another embodiment of the present disclosure;

FIG. 17 shows a structure schematic diagram of four light-emitting units provided by another embodiment of the present disclosure; and

FIG. 18 shows a structure schematic diagram of six light-emitting units provided by another embodiment of the present disclosure.

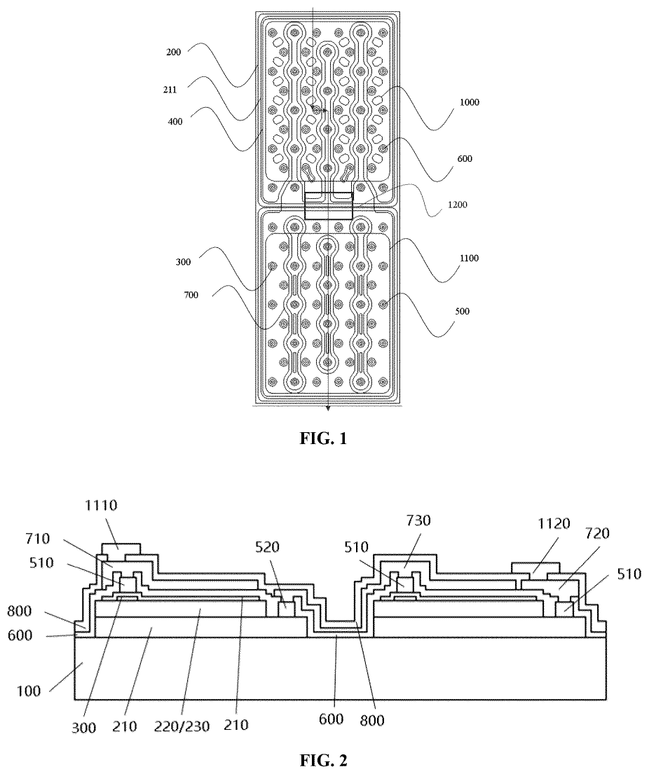

### REFERENCE NUMBERS

100-substrate; 101-protruding part; 102-recessed part;
200-isolation groove; 2011-first light-emitting unit;
2012-second light-emitting unit; 2013-third light-emitting unit; 2014-fourth light emitting unit;
2015-fifth light-emitting unit; 2016-sixth light-emitting unit; 210-N-type semiconductor layer;
211-MESA step; 220-light-emitting layer; 230-P-type semiconductor layer;
300-current blocking layer; 400-current extension layer; 500-first electrode layer;
510-first P-type electrode; 520-first N-type electrode; 600-first insulating layer;
700-second electrode layer; 710-second P-type electrode; 720-second N-type electrode;
730-PN connection electrode; 740-second electrode opening;
800-second insulating layer; 900-third electrode layer; 910-third P-type electrode;
920-third N-type electrode; 930-third center electrode; 940-third P-type through hole;
950-third N-type through hole; 1000-third insulating layer; 1100-bonding pad layer;
1110-P-type bonding pad; 1120-N-type bonding pad; 1200-ejector pin area; and
1300-ejector pin.

### DETAILED DESCRIPTION OF EMBODIMENTS

The technical solutions of the present disclosure will be clearly and completely described below in conjunction with drawings and embodiments. It will be understood by those skilled in the art that the embodiments described below are partial embodiments of the present disclosure and not all of them, and are used only for illustrating the present disclosure, and should not be regarded as limiting the scope of the present disclosure. Based on the embodiments of the present disclosure, all other embodiments obtained by a person of ordinary skill in the art without inventive efforts, shall fall within the scope of protection of the present disclosure. Where specific conditions are not indicated in the embodiments, they shall be performed in accordance with conventional conditions or those recommended by the manufacturer. The reagents or instruments used without indication of the manufacturer, are the conventional products that can be purchased commercially.

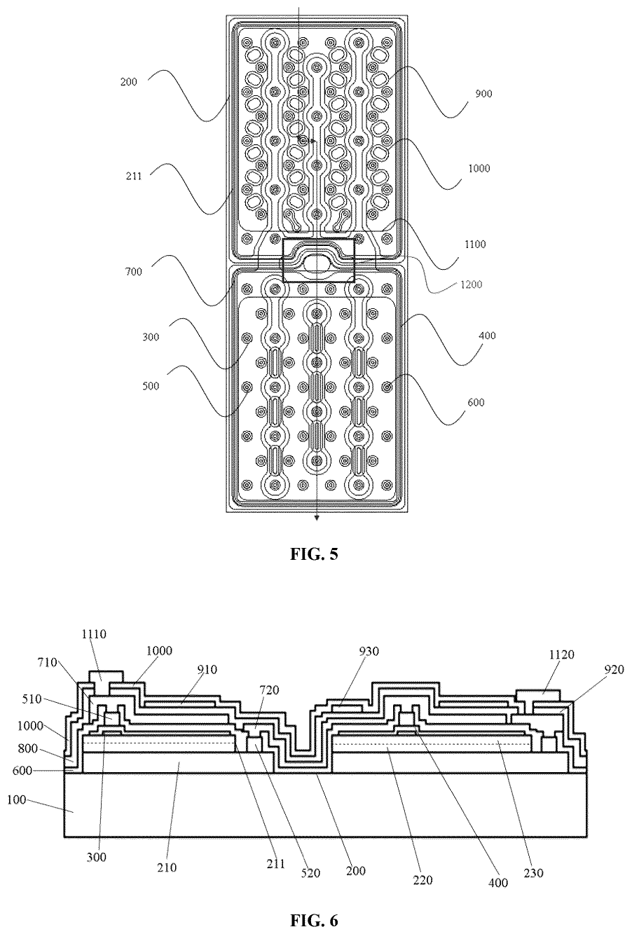

The embodiment of the present disclosure provides a flip high-voltage light-emitting diode, as shown in FIG. 5 and FIG. 6, including:
a base board;
at least two light-emitting units, located on the base board, wherein each two adjacent light-emitting units are isolated by an isolation groove 200, each light-emitting unit includes at least a N-type semiconductor layer 210, a light-emitting layer 220, a P-type semiconductor layer 230, and a first N electrode electrically connected to the N-type semiconductor layer 210 and a first P electrode electrically connected to the P-type semiconductor layer 230; and
at least one connection electrode, electrically connecting the P-type semiconductor layer 230 and the N-type semiconductor layer 210 of the adjacent light-emitting units respectively, wherein
at least one light-emitting unit has a protruding part 101 facing a center position of the flip high-voltage light-emitting diode, and the protruding part 101 is isolated from adjacent light-emitting unit by the isolation groove 200, wherein a width of the protruding part 101 is larger than a width of the isolation groove 200.

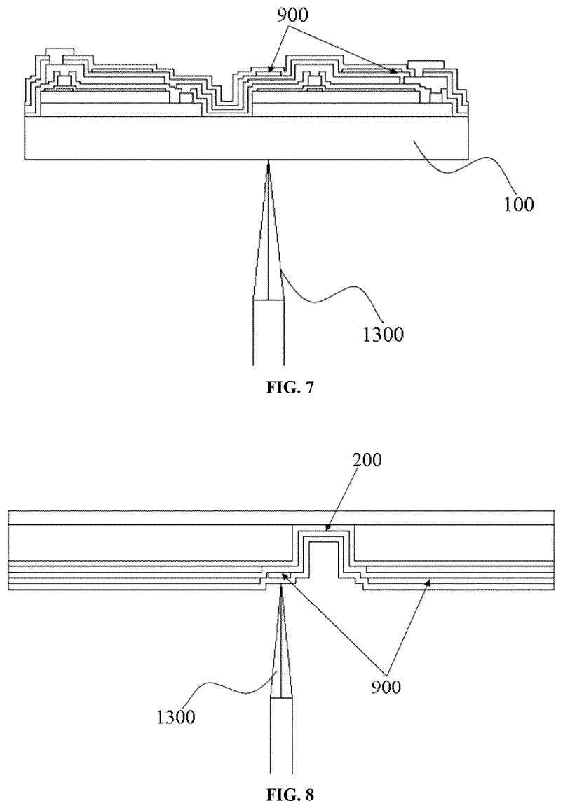

In this condition, the designs of using a sorting ejector pin and a wafer fixing ejector pin are separately shown in FIG. 7 and FIG. 8.

In a preferred embodiment of the present disclosure, the light-emitting unit with the protruding part 101 is defined as a first light-emitting unit 2011, and the other light-emitting unit closest to the first light-emitting unit 2011 is defined as a second light-emitting unit 2012, wherein the first light-emitting unit 2011 and the second light-emitting unit 2012 are of asymmetric structures.

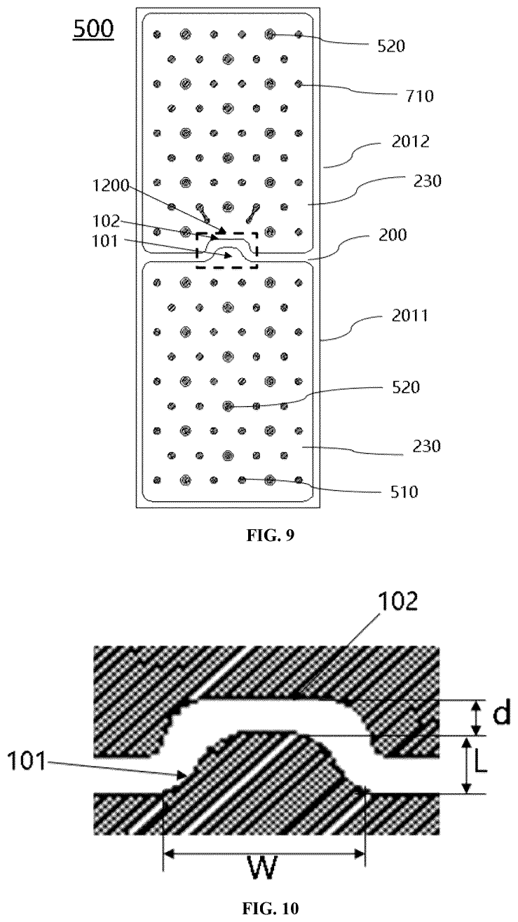

Specifically, as shown in FIG. 9, the first light-emitting unit 2011 has one protruding part 101, wherein the protruding part 101 serves as an ejector pin area 1200; and the second light-emitting unit 2012 has a corresponding recess, wherein the first light-emitting unit 2011 and the second light-emitting unit 2012 are isolated from each other by the isolation groove 200. The small dots in the figure represent the first P electrode, which is located on the P-type layer and electrically connected to the P-type layer; and the large dots represent the first N electrode, which is arranged on the N-type semiconductor layer 210, and electrically connected to the N-type layer.

In a preferred embodiment of the present disclosure, the second light-emitting unit 2012 has a recessed part 102 corresponding to the protruding part 101, wherein a projection of the protruding part 101 in a horizontal direction is of a shape of at least one of a circular arc, a square, a triangle, a rectangle, or a polygon (i.e., the shape of the protruding part 101 projected in a horizontal direction is at least one of a circular arc, a square, a triangle, a rectangle, or a polygon), but it is not limited thereto.

In a preferred embodiment of the present disclosure, as shown in FIG. 10, a relationship between a length W of the protruding part 101 and a length M of the first light-emitting unit 2011 is ⅓M≤W≤½M.

Further, L is the width of the isolation groove 200, wherein ½W≤L≤W, and L>d.

Further, 15 μm≤W≤50 μm, it includes, but is not limited to any point value or a range value of any two points of 15 μm, 20 μm, 25 μm, 30 μm, 35 μm, 40 μm, 45 μm, and 50 μm.

In a preferred embodiment of the present disclosure, the flip high-voltage light-emitting diode includes a first electrode layer 500, a second electrode layer 700, and a bonding pad electrode layer sequentially arranged in an outward extension direction of the base board.

As shown in FIG. 9, the first electrode layer 500 includes a plurality of first N-type electrodes 520 and first P-type electrodes 510 dispersedly arranged on each light-emitting unit respectively.

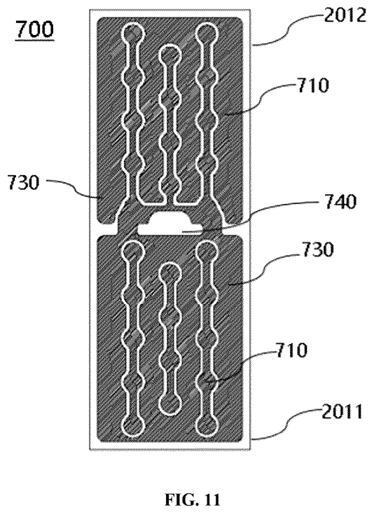

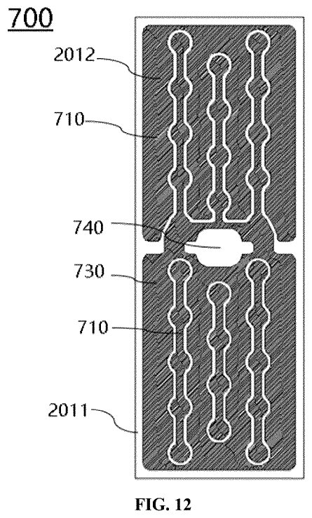

As shown in FIG. 11 and FIG. 12, the second electrode layer 700 includes a second P-type electrode 710, a second N-type electrode 720, and a PN connection electrode 730 connecting to the first P-type electrode 510 and the first N-type electrode 520 of adjacent light-emitting units, wherein the second N-type electrode, the second P-type electrode, and the PN connection electrode 730 are insulated from each other by white intervals in FIG. 11 and FIG. 12.

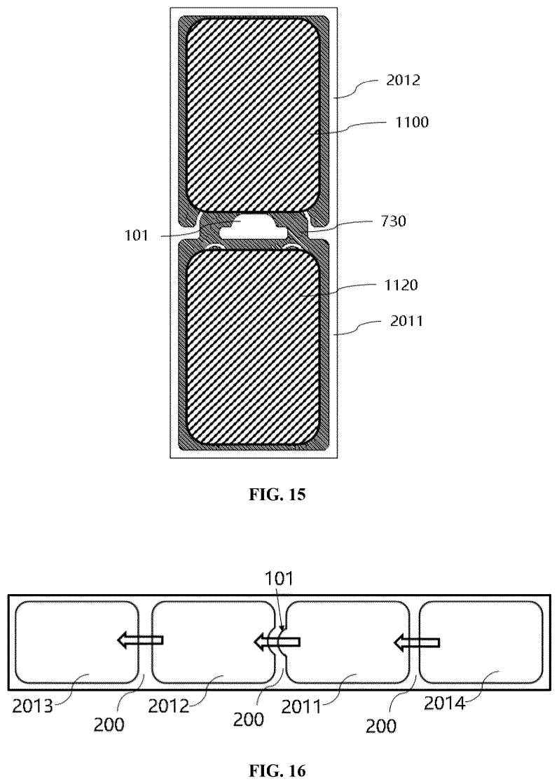

As shown in FIG. 15, the bonding pad electrode layer includes electrodes of the P-type bonding pad 1110 electrically connecting to the second P-type electrode 710 and electrodes of the N-type bonding pad 1120 electrically connecting to the second N-type electrode 720, wherein the ejector pin area 1200 is all insulating layer structures thereon, and does not contain a metal layer.

The PN connection electrode 730 includes one second electrode opening 740, and the second electrode opening 740 completely exposes the protruding part 101.

Specifically, when making evaporation of the second electrode layer 700, the pattern is formed from a negative photoresist, i.e., the photoresist served as a mask to deposit metal on a chip source; and then the photoresist is removed. In the design of the second electrode, the metal is not subjected to the evaporation on a position of the ejector pin where the PN connection electrode 730 is, so as to form the second electrode opening 740, so that opposite electrodes will not be short-circuited when the film layer at the ejector pin breaks, so as to improve the reliability of the chip.

The size of the second electrode opening 740 is larger than the size of the protruding part 101, and the protruding part 101 is entirely exposed, wherein the shape of the second electrode opening 740 is matched with the shape of the protruding part 101, or it can also be matched with a symmetrical pattern formed by the protruding part 101.

As shown in FIG. 11, the second electrode opening 740 is matched with the shape of the protruding part 101. As another embodiment, as shown in FIG. 12, the shape of the second electrode opening 740 is matched with the symmetrical pattern formed by the protruding part 101. The second electrode opening 740 is located in the center of the chip structure, and is symmetrically structured in both the X and Y directions.

In a preferred embodiment of the present disclosure, the second electrode opening 740 is arranged on the first light-emitting unit 2011, or arranged on the first light-emitting unit 2011 and partial isolation groove 200.

In a preferred embodiment of the present disclosure, the shape of the second electrode opening 740 is matched with the shape of the protruding part 101, or matched with a mirror shape of the protruding part 101.

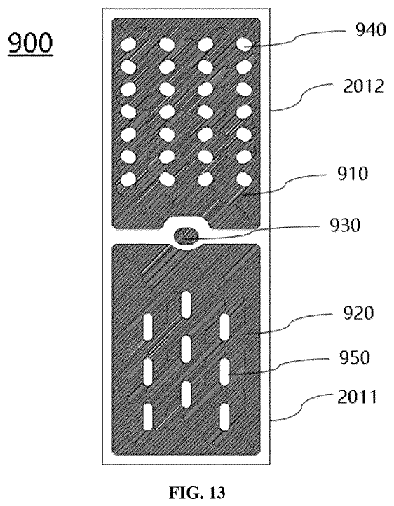

In another preferred embodiment of the present disclosure, as shown in FIG. 13, the flip high-voltage light-emitting diode further includes a third electrode layer 900 arranged between the second electrode layer 700 and the bonding pad electrode, and the third electrode layer 900 includes a third P-type electrode 910, a third N-type electrode 920, and a third center electrode 930 arranged on an upper part of the second electrode opening 740, wherein
the third P-type electrode 910, the third N-type electrode 920, and the third center electrode 930 are not connected to each other.

In a preferred embodiment of the present disclosure, the third P-type electrode 910 is provided with a third P-type through hole 940, and the third P-type through hole 940 is configured to expose the second P-type electrode 710.

In a preferred embodiment of the present disclosure, the third N-type electrode 920 is provided with a third N-type through hole 950, and the third N-type through hole 950 is configured to expose the second N-type electrode 720.

The present disclosure adds a third electrode layer 900, wherein the electrode layer is a neutral electrode, including a third N-type electrode 920 and a third N-type through hole 950 arranged on the first light-emitting unit 2011, a third P-type electrode 910 and a third P-type through hole 940 arranged on the second light-emitting unit 2012, and a third center electrode 930 arranged on the upper part of the second electrode opening 740, wherein the third center electrode 930 is arranged on the position of the ejector pin to improve the ejector pin resistant capability. The third center electrode 930, the third N electrode, the third P electrode, and the second electrodes are insulated from each other.

Further, the preparation process of the third electrode layer 900 is substantially the same as that of the second electrode layer 700. The material of the third electrode layer 900 may be selected from one or more metals of Cr, Al, Ti, Pt, Au, and Ni, but is not limited thereto.

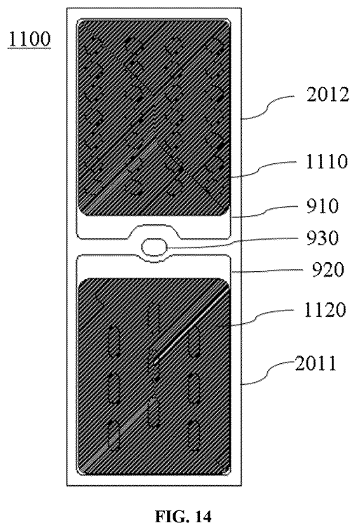

In a preferred embodiment of the present disclosure, the third electrode layer 900 is insulated from the second electrode layer 700 and the bonding pad electrode layer respectively. As shown in FIG. 14, the second electrode layer 700 is electrically connected to the bonding pad electrode layer. Specifically, a N-type bonding pad 1120 and a P-type bonding pad 1110 are provided, wherein the N-type bonding pad 1120 is electrically connected to the second N-type electrode 720 via the third N-type through hole 950, and the P-type bonding pad 1110 is electrically connected to the second P-type electrode 710 via the third P-type through hole 940. From the above steps, a complete flip high-voltage chip is formed.

In the process of using the ejector pin, a single pattern is designed on the ejector pin, which avoids the polarity connection, and at the same time greatly improves the ejector pin resistant ability of the chip, so as to improve the reliability of the chip in use.

Further, an area of the third electrode layer 900 occupies 60% ˜90% of a total area of the flip light-emitting diode.

Further, the third center electrode 930 is totally or partially arranged on the second electrode opening 740. The third center electrode 930 is located on the upper part of the protruding part 101, and is not arranged on the upper part of the isolation groove 200.

Further, the third center electrode 930 may be selected from one of the circular, elliptical, square, or polygonal shape, but is not limited to. Further, a largest circle is arranged in the third center electrode 930, and the minimum radius of the circle is ≥5 μm.

Further, at least 70% of the third center electrode 930 is arranged on the second electrode opening 740.

Further, the third center electrode 930 is arranged on the first light-emitting unit 2011.

Further, the third center electrode 930 is arranged on the center area of the flip high-voltage light-emitting diode.

In a preferred embodiment of the present disclosure, an outermost edge of the protruding part 101 is closer to the isolation groove 200 than an outermost edge of the third center electrode 930, and a difference between shortest horizontal distances between the two and the isolation groove is larger than 0 and smaller than or equal to 5 μm.

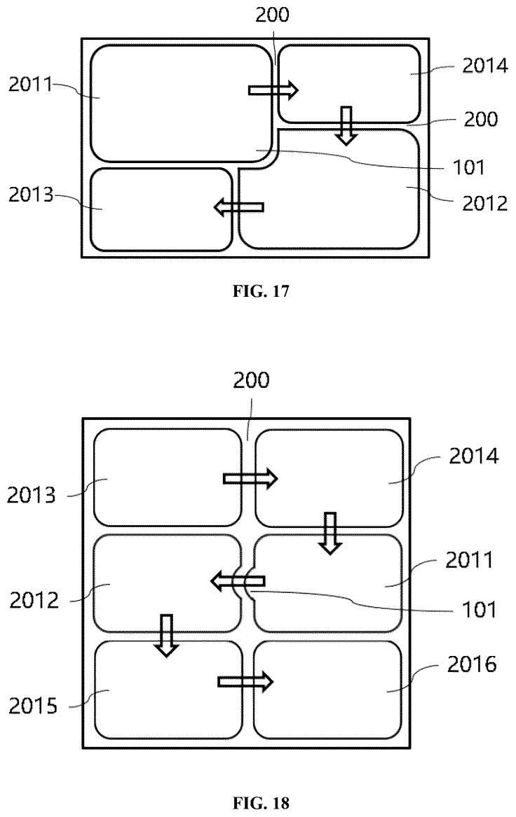

In a preferred embodiment of the present disclosure, as shown in FIG. 16 and FIG. 17, the number of the light-emitting units is not limited to two, but may be any positive number larger than or equal to 2, such as four light-emitting units. For example, FIG. 16 and FIG. 17 provide two different connection ways, but are not limited to this, which include the first light-emitting unit 2011, the second light-emitting unit 2012, the third light-emitting unit 2013, and the fourth light-emitting unit 2014 connected in sequence.

Additionally, as shown in FIG. 18, there are six light-emitting units, including the first light-emitting unit 2011, the second light-emitting unit 2012, the third light-emitting unit 2013, the fourth light-emitting unit 2014, the fifth light-emitting unit 2015, and the sixth light-emitting unit 2016 connected in sequence, wherein arrows in the figure represent the connection path of the PN electrode.

An optional preparation method of the flip high-voltage light-emitting diode, including the following steps.

(1) Providing a base board, and preparing the N-type semiconductor layer 210, the light-emitting layer 220, and the P-type semiconductor layer 230 sequentially on the base board, so as to form a LED wafer.

Specifically, the base board includes, but is not limited to the sapphire substrate 100; and the N-type semiconductor layer 210 may be N-type doped gallium nitride, and the P-type semiconductor layer 230 may be made of P-type doped gallium nitride, but they are not limited to these two types of semiconductors.

(2) Etching the LED wafer to obtain the MESA step 211.

(3) Depositing on the LED wafer sequentially to obtain the current blocking layer 300 and the current extension layer 400.

(4) Etching until the base board surface has the isolation groove 200; and separating the LED wafer by the isolation groove 200 after etching, so as to obtain the protruding part 101 and the recessed part 102 corresponding to the protruding part 101 between two adjacent light-emitting units.

(5) Depositing the first electrode layer 500 and the first insulating layer 600, and then depositing the second electrode layer 700.

Specifically, when making evaporation of the second electrode layer 700, the pattern is formed from the negative photoresist, i.e., the photoresist serves as the mask to deposit metal on the chip source; and then the photoresist is removed. In the design of the second electrode, the metal is not subjected to the evaporation on the position of the ejector pin where the PN connection electrode 730 is, so as to form the second electrode opening 740, so that opposite electrodes will not be short-circuited when the film layer at the ejector pin breaks, so as to improve the reliability of the chip.

(6) Depositing the second insulating layer 800 and the bonding pad layer 1100 sequentially.

Optionally, a third electrode layer 900 and a third insulating layer 1000 are added sequentially between the second insulating layer 800 and the bonding pad layer 1100, wherein the preparation method of the third electrode layer 900 is similar to that of the second electrode layer 700.

The third electrode layer 900 includes a third P-type electrode 910, a third N-type electrode 920, and a third center electrode 930, wherein the third P-type electrode 910, the third N-type electrode 920, and the third center electrode 930 are not connected to each other.

The third electrode layer 900 is insulated from the second electrode layer 700 and the bonding pad layer 1100.

The second electrode layer 700 is electrically connected to the bonding pad layer 1100 by the through holes on the third electrode.

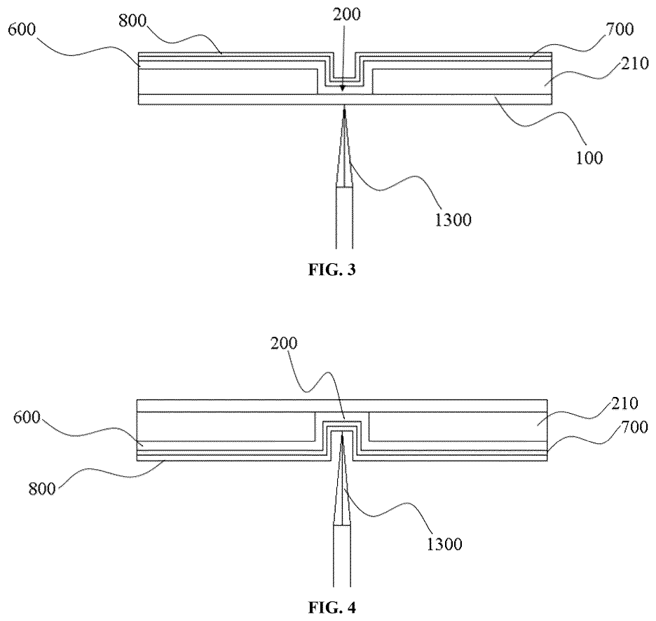

In the prior art, the ejector pin 1300 of the LED includes the sorting ejector pin used in sorting, and the wafer fixing ejector pin used by the customer to fix the wafer. During use, the positions of the sorting ejector pin and wafer fixing ejector pin are shown in FIG. 3 and FIG. 4, and are easily ruptured, so as to lead to leakage and failure. In the present disclosure, as shown in FIG. 7 and FIG. 8, the sorting ejector pin and the wafer fixing ejector pin are also used at the center during use. It has better reliability, and improves the service life of the chip.

Although the present disclosure has been illustrated and described by the embodiments, it should be noted that each of the above embodiments is used only to illustrate the technical solutions of the present disclosure, and is not a limitation thereof. Persons of ordinary skill in the art shall understand that, without departing from the spirit and scope of the present disclosure, the technical scheme described in the foregoing embodiments may be modified, or some or all of the technical features can be replaced by equivalent ones; and these modifications or replacements shall not remove the essence of the corresponding technical scheme from the scope of the technical solutions of each embodiment of the present disclosure. Therefore, it means that all the replacements and modifications falling within the scope of the present disclosure are included in the appended claims.

1. A flip high-voltage light-emitting diode, comprising:
a base board;
at least two light-emitting units, located on the base board, wherein each two adjacent light-emitting units are isolated by an isolation groove, and each of the light-emitting units comprises at least a N-type semiconductor layer, a light-emitting layer, a P-type semiconductor layer, and a first N electrode electrically connected to the N-type semiconductor layer and a first P electrode electrically connected to the P-type semiconductor layer; and
and at least one connection electrode, electrically connecting the P-type semiconductor layer and the N-type semiconductor layer of adjacent light-emitting units respectively, wherein
at least one light-emitting unit has a protruding part facing a center position of the flip high-voltage light-emitting diode, and the protruding part is isolated from the adjacent light-emitting units by the isolation groove, wherein a width of the protruding part is larger than a width of the isolation groove.

2. The flip high-voltage light-emitting diode according to claim 1, wherein the light-emitting unit with the protruding part is defined as a first light-emitting unit, and the other light-emitting unit closest to the first light-emitting unit is defined as a second light-emitting unit, wherein the first light-emitting unit and the second light-emitting unit are of asymmetric structures.

3. The flip high-voltage light-emitting diode according to claim 2, wherein the second light-emitting unit has a recessed part corresponding to the protruding part, wherein a projection of the protruding part in a horizontal direction is of a shape of at least one of a circular arc, a square, a triangle, a rectangle, or a polygon.

4. The flip high-voltage light-emitting diode according to claim 1, wherein a relationship between a length W of the protruding part and a length M of the first light-emitting unit is ⅓M≤W≤½M.

5. The flip high-voltage light-emitting diode according to claim 2, wherein the flip high-voltage light-emitting diode comprises a first electrode layer, a second electrode layer, and a bonding pad electrode layer sequentially arranged in an outward extension direction of the base board, wherein
the first electrode layer comprises a plurality of first N-type electrodes and first P-type electrodes dispersedly arranged on each of the light-emitting units respectively;
the second electrode layer comprises a second P-type electrode, a second N-type electrode, and a PN connection electrode connecting to the first P-type electrode and the first N-type electrode of the adjacent light-emitting units; and
the bonding pad electrode layer comprises electrodes of the P-type bonding pad electrically connecting the second P-type electrode and electrodes of the N-type bonding pad electrically connecting the second N-type electrode, wherein
the PN connection electrode comprises one second electrode opening, and the second electrode opening completely exposes the protruding part.

6. The flip high-voltage light-emitting diode according to claim 5, wherein the second electrode opening is arranged on the first light-emitting unit, or arranged on the first light-emitting unit and a partial isolation groove.

7. The flip high-voltage light-emitting diode according to claim 5, wherein a shape of the second electrode opening is matched with a shape of the protruding part, or matched with a mirror shape of the protruding part.

8. The flip high-voltage light-emitting diode according to claim 5, wherein the flip high-voltage light-emitting diode further comprises a third electrode layer arranged between the second electrode layer and the bonding pad electrode, and the third electrode layer comprises a third P-type electrode, a third N-type electrode, and a third center electrode arranged on an upper part of the second electrode opening, wherein
the third P-type electrode, the third N-type electrode, and the third center electrode are not connected to each other

9. The flip high-voltage light-emitting diode according to claim 8, wherein the third electrode layer is insulated from the second electrode layer and the bonding pad electrode layer respectively, wherein
the second electrode layer is electrically connected to the bonding pad electrode layer

10. The flip high-voltage light-emitting diode according to claim 9, wherein an outermost edge of the protruding part is closer to the isolation groove than an outermost edge of the third center electrode, wherein a difference between shortest horizontal distances is larger than 0 and smaller than or equal to 5 μm, and the shortest horizontal distances are distances separately between the outermost edge of the protruding part and the isolation groove and between the outermost edge of the third center electrode and the isolation groove.

11. The flip high-voltage light-emitting diode according to claim 4, wherein 15μm≤W≤50 μm.

12. The flip high-voltage light-emitting diode according to claim 8, wherein
the third P-type electrode is provided with a third P-type through hole, and the third P-type through hole is configured to expose the second P-type electrode

13. The flip high-voltage light-emitting diode according the claim 8, wherein the third N-type electrode is provided with a third N-type through hole, and the third N-type through hole is configured to expose the second N-type electrode.

14. The flip high-voltage light-emitting diode according to claim 9, wherein
an area of the third electrode layer occupies 60% ˜90% of a total area of the flip light-emitting diode.

15. The flip high-voltage light-emitting diode according to claim 9, wherein the third center electrode is totally or partially arranged on the second eletrode opening.

16. The flip high-voltage light-emitting diode according to claim 9, wherein at least 70% of the third center electrode is arranged on the second electrode opening.

17. The flip high-voltage light-emitting diode according to claim 9, wherein the third center electrode is arranged on the first light-emitting unit.

18. The flip high-voltage light-emitting diode according to claim 9, wherein the third center electrode is arranged on a center area of the flip high-voltage light-emitting diode.
